(19) United States
(12) Patent Application Publication
(10) Pub. No.: US 2017/0146568 A1
(43) Pub. Date: May 25, 2017

(54) ELECTRONIC TEST EQUIPMENT

(71) Applicant: WinWay Tech. Co., Ltd., Kaohsiung City (TW)

(72) Inventors: Jun-Xian LIU, Kaohsiung City (TW); Cheng-Hui LIN, Kaohsiung City (TW); Chia-Pin SUN, Kaohsiung City (TW); Hsin-Chieh LU, Kaohsiung City (TW)

(21) Appl. No.: 14/946,157

(22) Filed: Nov. 19, 2015

(51) Int. Cl. G01R 1/073; G01R 1/04; G01R 31/28

(52) U.S. Cl. CPC G01R 1/073; G01R 31/28; G01R 1/04

(57) ABSTRACT

An electronic test equipment is adapted to test an electronic component. The electronic component has a circuit body and a plurality of connectors that are electrically connected to the circuit body. The electronic test equipment includes a metallic test seat and a plurality of spring probes. The metallic test seat is adapted to support the circuit body thereon, and is formed with a plurality of spaced-apart probe holes extending therethrough and possessing diameters that are substantially the same. Each of the probe holes is adapted to receive a corresponding one of the connectors. The spring probes are respectively and entirely positioned within the probe holes, and are adapted to electrically contact the connectors.

### FIELD

The disclosure relates to a test equipment, more particularly to an electronic test equipment.

### BACKGROUND

Referring to FIGS. 1 and 2, a conventional electronic test equipment is illustrated. The conventional electronic test equipment is capable of testing an electronic component 100 for examining performances thereof, and includes a metallic test seat 11 and a plurality of spring probes 12. The metallic test seat 11 serves to support the electronic component 100 thereon, and is formed with a plurality of probe holes 111. The spring probes 12 are respectively and entirely positioned inside of the probe holes 111, and electrically contact the electronic component 100 for conducting various tests thereon. However, although the metallic test seat 11 shields the spring probes 12 disposed therewithin, since the internal diameter of each probe hole 111 is non-uniform, a mismatch between an input impedance of the electronic component 100 and an output impedance of the electronic test equipment may occur, thereby causing undesired reflections during the signal transfer, which may lead to signal distortion and inaccurate test results.

### SUMMARY

Therefore, the object of the disclosure is to provide an electronic test equipment that can alleviate at least one of the drawbacks associated with the abovementioned prior art.

According to the disclosure, an electronic test equipment is adapted to test an electronic component. The electronic component has a circuit body and a plurality of connectors that are electrically connected to the circuit body. The electronic test equipment includes a metallic test seat and a plurality of spring probes. The metallic test seat is adapted to support the circuit body thereon, and is formed with a plurality of spaced-apart probe holes extending therethrough and possessing diameters that are substantially the same. Each of the probe holes is adapted to receive a corresponding one of the connectors. The spring probes are respectively and entirely positioned within the probe holes, and are adapted to electrically contact the connectors.

### BRIEF DESCRIPTION OF THE DRAWINGS

Other features and advantages of the disclosure will become apparent in the following detailed description of the embodiment with reference to the accompanying drawings, of which:

FIG. 1 is a sectional view illustrating a conventional electronic test equipment;

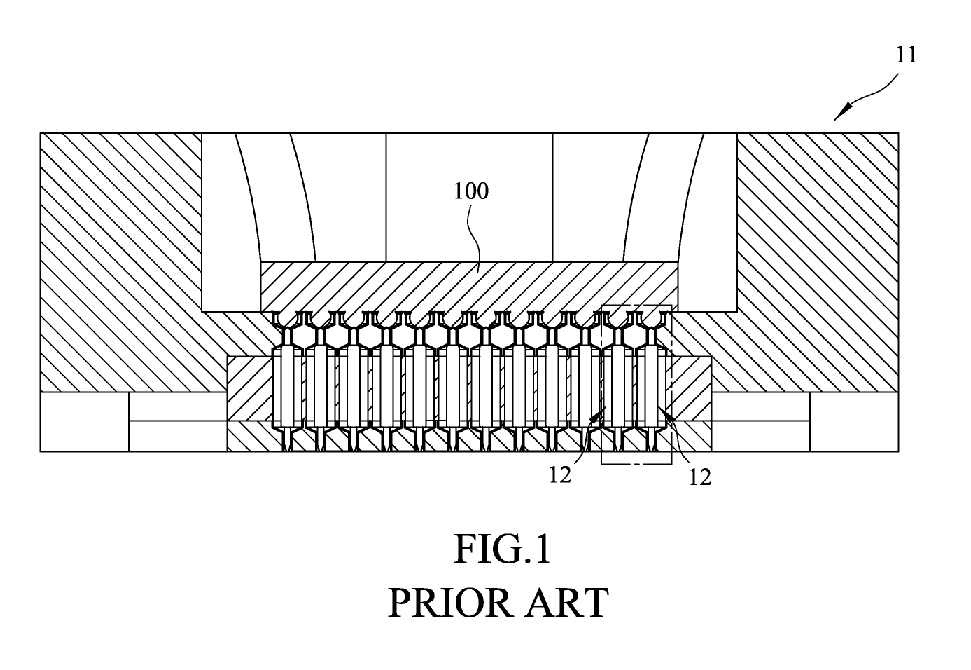

FIG. 2 is an enlarged fragmentary sectional view illustrating probe holes of the conventional electronic test equipment;

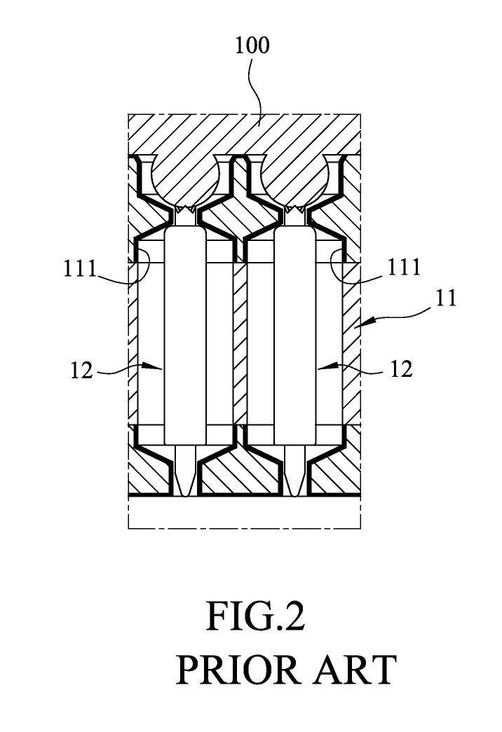

FIG. 3 is a sectional view illustrating an embodiment of an electronic test equipment according to the disclosure;

FIG. 4 is an enlarged fragmentary sectional view of the embodiment, illustrating the embodiment being in electrical contact with an electronic component; and

FIG. 5 is a view similar to FIG. 4, but illustrating the embodiment being in electrical contact with the electronic component in another manner.

### DETAILED DESCRIPTION

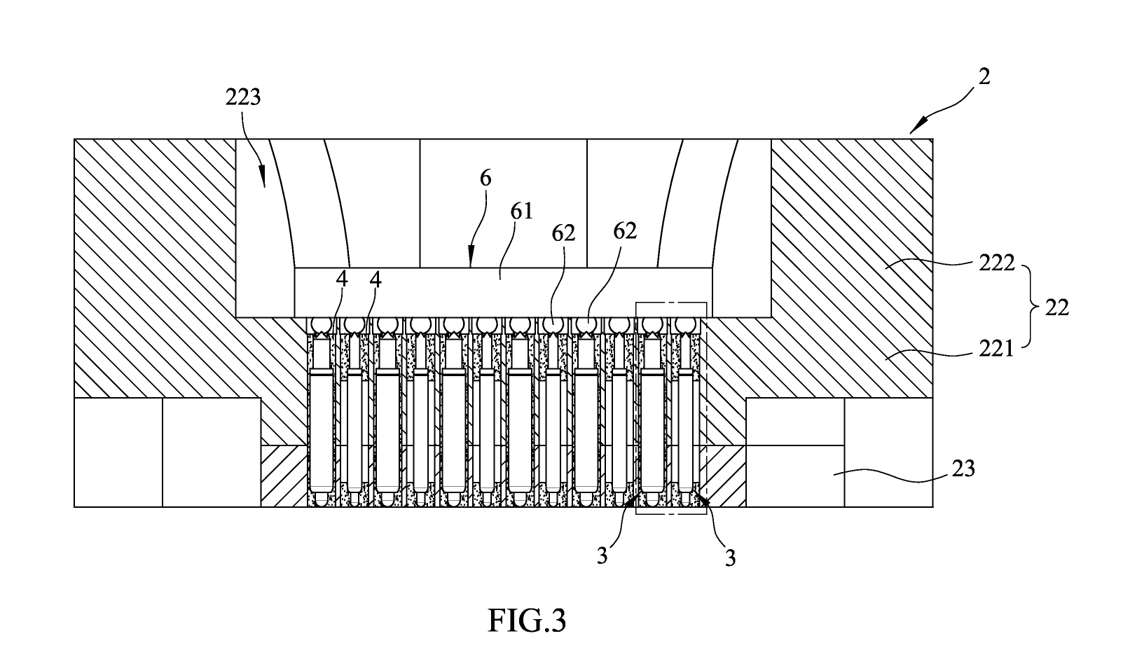

Referring to FIG. 3, an embodiment of an electronic test equipment according to the disclosure is adapted to test an electronic component 6. The electronic component 6 has a circuit body 61 and a plurality of connectors 62 that are electrically connected to the circuit body 61. The electronic test equipment includes a metallic test seat 2, a plurality of spring probes 3, and a plurality of electric insulators 4.

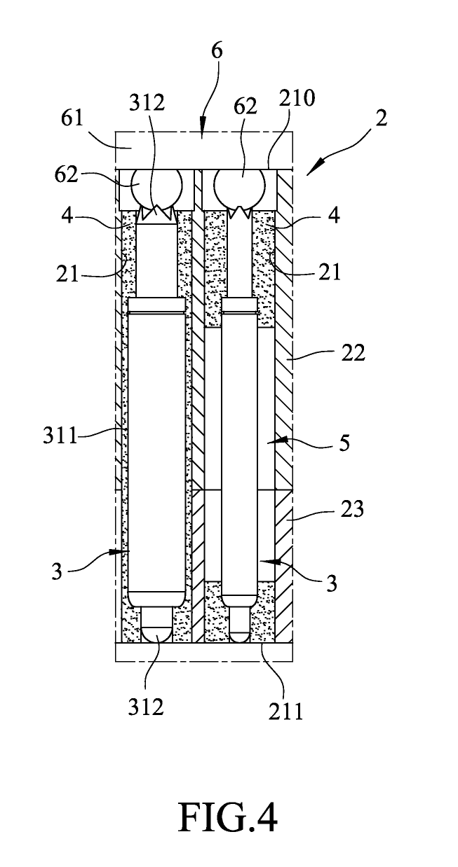

Referring further to FIG. 4, the test seat 2 includes an upper body 22 that is adapted to support the circuit body 61 of the electronic component 6 thereon, and a lower body 23 that is connected to the upper body 22. The upper body 22 has a base wall 221 connected to the lower body 23, and a surrounding wall 222 protruding upwardly from a periphery of the base wall 221 and cooperating with the base wall 221 to define a receiving space 223 that is adapted to receive the electronic component 6. It should be noted that the upper and lower bodies 22, 23 may be formed as one piece.

Moreover, the test seat 2 is formed with a plurality of spaced-apart probe holes 21 extending through the upper and lower bodies 22, 23, and possessing diameters that are substantially the same. Each of the probe holes 21 is adapted to receive a corresponding one of the connectors 62. Specifically, the diameter of each probe hole 21 is within ±10% deviation from a reference diameter. Each of the probe holes 21 has a first opening 210 adapted to receive a corresponding one of the connectors 62, and a second opening 211 opposite to the first opening 210.

The spring probes 3 are respectively and entirely positioned within the probe holes 21 of the test seat 2, and each of the spring probes 3 is adapted to electrically contact a corresponding one of the connectors 62 of the electronic component 6. The spring probes 3 has a side surrounding surface 311, and opposite end portions 312 that are disposed at opposite sides of the side surrounding surface 311. One of the end portions 312 is adapted to electrically contact the corresponding one of the connectors 62.

More specifically, the spring probes 3 serve three functions—power source connection, grounding and signal transfer. At least one spring probe 3 is for power source connection, at least one spring probe 3 is for grounding, and the other spring probes 3 are for signal transfer.

The at least one spring probe 3 serving the grounding function electrically and directly contacts the test seat 2. The electric insulators 4 are disposed respectively inside of only the probe holes 21 that retain the spring probes 3 for the functions of power source connection and signal transfer, and are respectively sleeved on the side surrounding surfaces 311 of the corresponding spring probes 3 for respectively positioning the spring probes 3. As shown in FIG. 4, the side surrounding surface 311 of the spring probe 3 for power source connection, which is illustrated as the left one of the spring probes 3 in FIG. 4, is entirely surrounded by a respective one of the insulators 4 so as to prevent short circuit. The side surrounding surface 311 of each of the probes 3 for signal transfer is partially covered by the corresponding insulator 4, such that an air gap 5 is defined between the test seat 2 and the probe 3.

As shown in FIG. 3, in an operation of the electronic test equipment according to the disclosure, when the electronic component 6 is placed thereon, with the connectors 62 being electrically connected to the spring probes 3, a test circuit is formed. At this time, the metallic test seat 2 surrounds the electronic component 6 with the surrounding wall 222, and shields the spring probes 3 with the connectors 62 respectively plugging the probe holes 21 to prevent exposure of the connectors 62 and the spring probes 3 from the probe holes 21, such that an electromagnetic shielding can be achieved to isolate the test circuit from any external interference.

Moreover, since the probe holes 21 of the test seat 2 are all formed with substantially the same diameter, the electronic test equipment according to the disclosure can approach an impedance matching between an input impedance of the electronic component 6 and an output impedance of the electronic test equipment and can prevent signal reflections to secure the operational accuracy by simply adjusting the sizes of the air gaps 5. Therefore, the electronic test equipment according to the disclosure is able to perform accurate examinations on the electronic component 6.

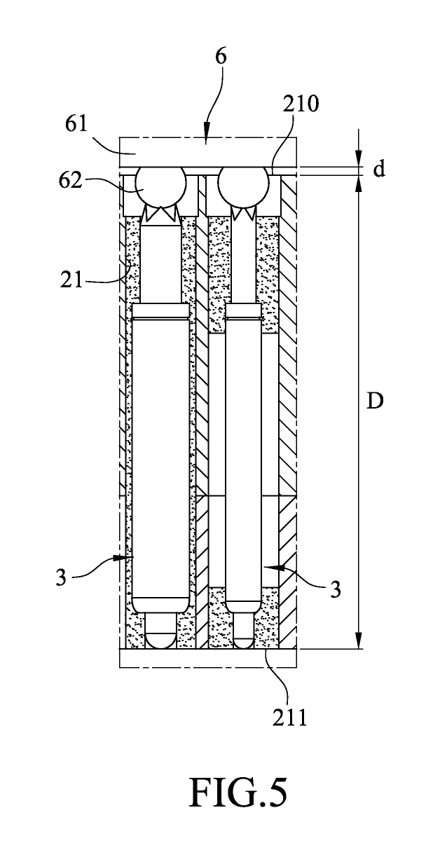

It should be further noted that, the connectors 62 may be partially exposed from the probe holes 21 to achieve the same electromagnetic shielding as long as the exposure of each of the connectors 62 is limited at a specific level. Specifically, as shown in FIG. 5, for each of the probe holes 21, a distance (d) between the first opening 210 and the circuit body 61 is not larger than 5% of another distance (D) between said first and second openings 210, 211.

While the present invention has been described in connection with what is considered the exemplary embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An electronic test equipment adapted to test an electronic component, the electronic component having a circuit body and a plurality of connectors that are electrically connected to the circuit body, said electronic test equipment comprising:
a metallic test seat that is adapted to support the circuit body thereon, and that is formed with a plurality of spaced-apart probe holes extending therethrough and possessing diameters that are substantially the same, each of said probe holes being adapted to receive a corresponding one of the connectors; and
a plurality of spring probes that are respectively and entirely positioned within said probe holes, and that are adapted to electrically contact the connectors.

2. The electronic test equipment as claimed in claim 1, further comprising a plurality of electric insulators, each of which is disposed inside of a corresponding one of said probe holes of said test seat, and positions a corresponding one of said spring probes.

3. The electronic test equipment as claimed in claim 2, wherein each of said spring probes has a side surrounding surface, and opposite end portions that are disposed at opposite sides of said side surrounding surface, one of said end portions being adapted to electrically contact the respective one of the connectors, at least one of said electric insulators surrounding said side surrounding surface of a corresponding one of said electric insulators entirely.

4. The electronic test equipment as claimed in claim 2, wherein each of said spring probes has a side surrounding surface, and opposite end portions that are disposed at opposite sides of said side surrounding surface, a portion of said side surrounding surface of at least one of said spring probes being sleeved with a respective one of said electric insulators such that an air gap is defined between said test seat and the at least one of said spring probes, one of said end portions being adapted to electrically contact the respective one of the connectors.

5. The electronic test equipment as claimed in claim 1, wherein:
said test seat includes
an upper body that is adapted to support the circuit body of the electronic component thereon, and
a lower body that is connected to said upper body; and
said probe holes extend through said upper and lower bodies.

6. The electronic test equipment as claimed in claim 5, wherein said upper body of said test seat has:
a base wall connected to said lower body; and
a surrounding wall protruding upwardly from a periphery of said base wall and cooperating with said base wall to define a receiving space that is adapted to receive the electronic component.

7. The electronic test equipment as claimed in claim 1, wherein the diameter of each of said probe holes on said test seat is within ±10% deviation from a reference diameter.

8. The electronic test equipment as claimed in claim 1, wherein:
each of said probe holes has a first opening adapted to receive a respective one of the connectors, and a second opening opposite to said first opening; and
a distance between said first opening and the circuit body is not larger than 5% of a distance between said first and second openings.
